(19) United States
(12) Patent Application Publication
(10) Pub. No.: US 2013/0221074 A1
(43) Pub. Date: Aug. 29, 2013

(54) SOLDER BUMP STRETCHING METHOD

(71) Applicants: Cheng-Chang WEI, Taipei City (TW); Su-Chun YANG, Hsinchu County (TW); Hsiao-Yun CHEN, Hsinchu County (TW); Chih-Hang TUNG, Hsinchu (TW); Da-Yuan SHIH, Hsinchu (TW); Chen-Hua YU, Hsinchu City (TW)

(72) Inventors: Cheng-Chang WEI, Taipei City (TW); Su-Chun YANG, Hsinchu County (TW); Hsiao-Yun CHEN, Hsinchu County (TW); Chih-Hang TUNG, Hsinchu (TW); Da-Yuan SHIH, Hsinchu (TW); Chen-Hua YU, Hsinchu City (TW)

(73) Assignee: TAIWAN SEMICONDUCTOR MANUFACTURING COMPANY, LTD., Hsinchu (TW)

(21) Appl. No.: 13/406,198

(22) Filed: Feb. 27, 2012

(51) Int. Cl. H05K 13/04

(52) U.S. Cl. CPC H05K 13/0465
USPC 228/125

(57) ABSTRACT

A method includes heating a solder bump above a melting temperature of the solder bump. The solder bump is stretched to increase a height of the solder bump. The solder bump is cooled down.

### TECHNICAL FIELD

The present disclosure relates generally to an integrated circuit and more particularly to a solder bump.

### BACKGROUND

Solder bumps, used in flip-chip solder joints for example, are usually assembled by aligning and placing a chip on a substrate, then reflowing the solder bumps in a conveyer oven. The grain orientation of the solder bump element, e.g., Sn, could not be controlled, and the reflowed solder joint has random grain orientation. Depending on the local grain orientation around a joint between a solder bump and a conductive pad or an under bump metal (UBM), early failure may occur at the joint due to solder material dissolution caused by, for example, electromigration (EM).

### BRIEF DESCRIPTION OF THE DRAWINGS

Reference is now made to the following descriptions taken in conjunction with the accompanying drawings, in which:

FIGS. 1A-1E are cross-sectional views of an exemplary solder bump at various intermediate steps of a solder bump stretching process according to some embodiments;

FIG. 2 is a diagram of grain orientation angle of an exemplary solder bump element crystal such as Sn; and

FIG. 3 is a picture of an exemplary solder bump stretched by the process in FIGS. 1A-1E according to some embodiments.

### DETAILED DESCRIPTION

The making and using of various embodiments are discussed in detail below. It should be appreciated, however, that the present disclosure provides many applicable inventive concepts that can be embodied in a wide variety of specific contexts. The specific embodiments discussed are merely illustrative of specific ways to make and use, and do not limit the scope of the disclosure.

In addition, the present disclosure may repeat reference numerals and/or letters in the various examples. This repetition is for the purpose of simplicity and clarity and does not in itself dictate a relationship between the various embodiments and/or configurations discussed. Moreover, the formation of a feature on, connected to, and/or coupled to another feature in the present disclosure that follows may include embodiments in which the features are formed in direct contact, and may also include embodiments in which additional features may be formed interposing the features, such that the features may not be in direct contact. In addition, spatially relative terms, for example, “lower,” “upper,” “horizontal,” “vertical,” “above,” “below,” “up,” “down,” “top,” “bottom,” etc. as well as derivatives thereof (e.g., “horizontally,” “downwardly,” “upwardly,” etc.) are used for ease of the present disclosure of one features relationship to another feature. The spatially relative terms are intended to cover different orientations of the device including the features.

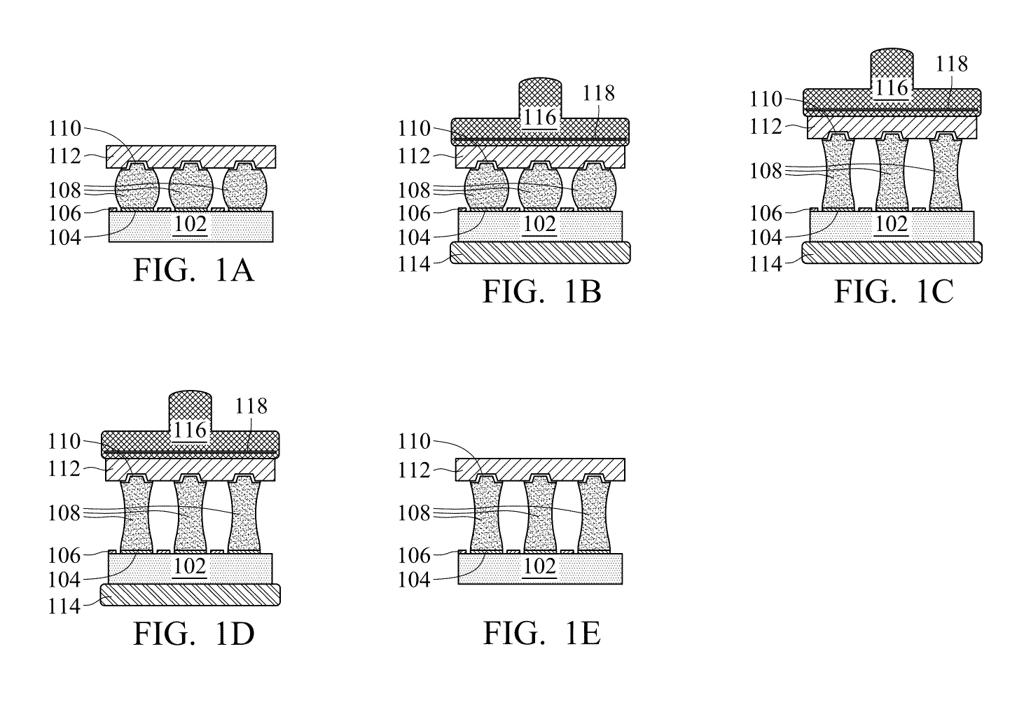

FIGS. 1A-1E are cross-sectional views of an exemplary solder bump at various intermediate steps of a solder bump stretching process according to some embodiments. In FIG. 1A, a substrate 102 is jointed with a top die 112 after a reflow process of the solder bumps 108. The substrate 102 is shown with pads 104 for electrical connections using solder bumps 108. The substrate 102 provides support for the electrical connections to a top die 112 through the solder bumps 108. The substrate 102 can be, for example, a silicon substrate, an interposer, another die, or a printed circuit board (PCB). The pads 104 formed over the substrate 102 comprise electrically conductive material, such as metal (copper, aluminium, etc.).

A solder mask 106 disposed over the substrate 102 provides a protective coating, e.g., for the copper traces on the substrate 102, and prevents solder bumps 108 from bridging conductors, thereby preventing short circuits. The solder mask 106 can be liquid photo-imageable solder mask (LPSM) or dry film photo-imageable solder mask (DFSM), and comprises epoxy, or a lacquer-like layer of polymer in some embodiments.

The solder bumps 108 disposed over the substrate 102 and pads 104 can be micro bumps, ball grid array (BGA) solder balls, or any other suitable solder structure. For example, some micro bumps has a diameter of about 2 μm-120 μm, and some BGA solder balls has a diameter of about 100 μm-500 μm in some embodiments. The solder bumps 108 comprise solder materials such as Sn, Ag, Cu, any combination there of, or any other suitable material.

Solder bumps 108 can be formed or placed on under bump metal (UBM) 110 in many ways, including evaporation, electroplating, printing, jetting, stud bumping, direct placement, or any other suitable method. The UBM 110 facilitates soldering using solder bumps 108 for electrical connections to the top die 112. The pads 104, solder mask 106, solder bumps 108, and UBM 110 can be fabricated using any suitable processes and/or materials known in the art.

In FIG. 1B, the package including the substrate 102 and the top die 112 is then placed in a thermal compression bonder (TCB). The top holder (i.e., bonder head) 116 of the TCB is bonded to the top die 112 above the solder bumps 108 and a bottom holder 114 of the TCB is bonded to the substrate 102 below the solder bumps 108. The bonding of the top holder 116 and the top die 112 and the bonding of the bottom holder 114 and the substrate 102 can be performed by vacuum suction, for example. Then the solder bumps 108 are heated above the melting temperature of the solder bumps 108 by using a heat element 118 in the top holder 116. In one example, the solder bumps 108 are heated above 300° C. The heat element 118 can be an electrical wire, for example. In some embodiments, the heating temperature is above the melting point of the solder used. In some embodiments, the temperature profile can be controlled separately on the two sides of the solder bumps 108, and/or by leaving the bottom holder 114 at a room temperature.

In FIG. 1C, the top holder 116 and the bottom holder 114 of the TCB are used to pull the top die 112 to a controlled height, and the shape of molten solder bumps 108 is simultaneously changed. The solder bumps 108 are stretched to manipulate and change the shape, height, and microstructure, e.g., to increase the height of the solder bumps 108. Even though the top holder 116 and the bottom holder 114 of the TCB are used to stretch the solder bump 108 to increase its height, any other suitable method can be used in other embodiments.

In FIG. 1D, the heat in the top holder 116 is stopped or removed to allow the solder bumps 108 to solidify. The solder bumps 108 are allowed to cool down in a controlled manner. In one example, the solder bumps 108 are cooled down at a room temperature. In FIG. 1E, the top holder 116 and the bottom holder 114 are removed.

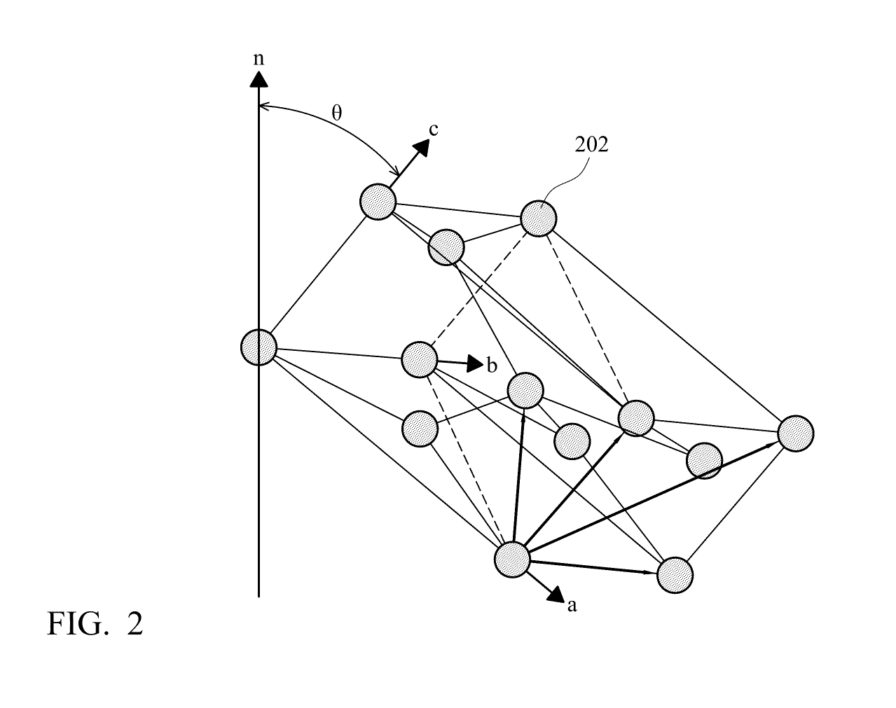

After the stretching process in FIGS. 1A-1E, solder bumps 108 have an increased grain orientation angle. FIG. 2 is a diagram of the grain orientation angle of an exemplary solder bump element crystal such as β-Sn. As shown in FIG. 2, the grain orientation angle θ is the angle between the short crystal axis (c-axis) of the main element 202 (of the solder bumps 108 in FIGS. 1A-1E) and the normal n-axis (of the substrate 102 or of the pad 104 in FIGS. 1A-1E), which is the current flow direction. Long crystal axis, i.e., a-axis and b-axis, are also shown in FIG. 2 for references.

The n-axis can be considered as the current flow direction, and a small grain orientation angle θ between the c-axis and the n-axis can facilitate a fast atomic migration and result in an earlier EM failure. In some embodiments, the main element of the solder bumps 108 is Sn and the increased orientation angle after the stretching process in FIGS. 1A-1E is above 50°. A microanalysis technique such as Electron Backscatter Diffraction (EBSD) can be used with electron microscopes to determine the crystal structure of the sample and estimate the grain orientation angle.

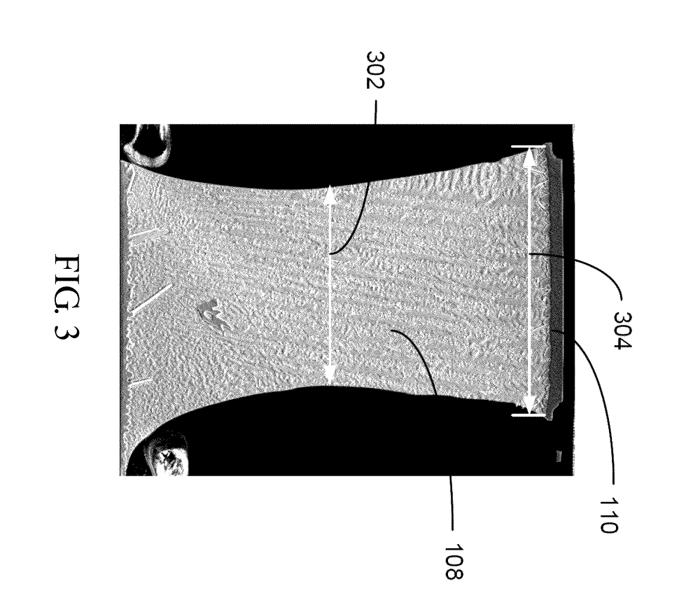

FIG. 3 is a picture of an exemplary solder bump 108 stretched by the process in FIGS. 1A-1E according to some embodiments. The ratio of the center width 302 of the solder bump 108 over the top contact width 304 of the solder bump 108 is from 0.6 to 1.0 after the stretching in some embodiments. In one example, a solder bump 108 having a height of about 160 μm is stretched to the height of about 260 μm and the ratio of the center width 302 (about 170 μm) over the top contact width 304 (about 240 μm) is about 0.7.

Also, the solder bump 108 has an increased portion of a lamellar structure (a thin plate or pillar-like structure) after the stretching process, as shown in FIG. 3. The lamellar structure can reduce crack propagation because the grain boundaries are close to vertical relative to a horizontal crack propagation direction. In FIG. 3, coarse dendrites are also observed. Even though an hour-glass shape (having a longer top width than the center width) is shown in FIG. 3, different shapes are possible, including column or cylinder-shape, a barrel shape, or ball shape, etc., by using different solder volume or different controlled stretching height.

The stretching process described in FIGS. 1A-1E can also improve thermal mechanical reliability of solder bump joints. The increased height and/or the hour-glass shape in some embodiments effectively reduce the strain in the solder bumps 108. In some exemplary embodiments, the fatigue life of solder bumps 108 using the stretching method in FIGS. 1A-1E was enhanced up to 4-5 times compared to solder bumps 108 without stretching.

According to some embodiments, a method includes heating a solder bump above a melting temperature of the solder bump. The solder bump is stretched to increase the height of the solder bump. The solder bump is cooled down.

A skilled person in the art will appreciate that there can be many embodiment variations of this disclosure. Although the embodiments and their features have been described in detail, it should be understood that various changes, substitutions and alterations can be made herein without departing from the spirit and scope of the embodiments. Moreover, the scope of the present application is not intended to be limited to the particular embodiments of the process, machine, manufacture, and composition of matter, means, methods and steps described in the specification. As one of ordinary skill in the art will readily appreciate from the disclosed embodiments, processes, machines, manufacture, compositions of matter, means, methods, or steps, presently existing or later to be developed, that perform substantially the same function or achieve substantially the same result as the corresponding embodiments described herein may be utilized according to the present disclosure.

The above method embodiment shows exemplary steps, but they are not necessarily required to be performed in the order shown. Steps may be added, replaced, changed order, and/or eliminated as appropriate, in accordance with the spirit and scope of embodiment of the disclosure. Embodiments that combine different claims and/or different embodiments are within the scope of the disclosure and will be apparent to those skilled in the art after reviewing this disclosure.

What is claimed is:

1. A method, comprising:
heating a solder bump above a melting temperature of the solder bump;
stretching the solder bump to increase a height of the solder bump; and
cooling down the solder bump.

2. The method of claim 1, further comprising bonding a top holder to a top die above the solder bump.

3. The method of claim 2, wherein bonding the top holder is achieved by vacuum suction.

4. The method of claim 2, wherein heating the solder bump is performed by using a heat element in the top holder.

5. The method of claim 4, wherein the heat element comprises an electrical wire.

6. The method of claim 1, further comprising bonding a bottom holder to a substrate below the solder bump.

7. The method of claim 1, wherein stretching the solder bump increases a grain orientation angle between a short crystal axis of a main element of the solder bump and a normal axis of a substrate below the solder bump.

8. The method of claim 7, wherein the main element is Sn.

9. The method of claim 7, wherein the angle is above 50°.

10. The method of claim 1, wherein the heating is above 300° C.

11. The method of claim 1, wherein a ratio of a center width of the solder bump over a top contact width of the solder bump is from 0.6 to 1.0 after the stretching.

12. The method of claim 1, wherein the solder bump has an increased portion of a lamellar structure after the stretching.

13. A method, comprising:
bonding a top holder to a top die having a solder bump;
heating a solder bump above a melting temperature of the solder bump;
stretching the solder bump to increase a height of the solder bump in order to increases a grain orientation angle between a short crystal axis of a main element of the solder bump and a normal axis of a substrate below the solder bump; and
cooling down the solder bump.

14. The method of claim 13, wherein the bonding is achieved by vacuum suction.

15. The method of claim 13, wherein heating the solder bump is performed by using a heat element in the top holder.

16. The method of claim 15, wherein the heat element comprises an electrical wire.

17. The method of claim 13, further comprising bonding a bottom holder to a substrate below the solder bump.

18. The method of claim 13, wherein the angle is above 50°.

19. The method of claim 13, wherein a ratio of a center width of the solder bump over a top contact width of the solder bump is from 0.6 to 1.0 after the stretching.

20. A method, comprising:
bonding a top holder to a top die having a solder bump, wherein the solder bump includes Sn;
heating a solder bump above a melting temperature of the solder bump using a heat element in the top holder;
stretching the solder bump to increase a height of the solder bump in order to increases a grain orientation angle between a short crystal axis of Sn in the solder bump and a normal axis of a substrate below the solder bump, wherein a ratio of a center width of the solder bump over a top contact width of the solder bump is from 0.6 to 1.0 and the solder bump has an increased portion of a lamellar structure after the stretching; and
cooling down the solder bump.
